(19) United States
(12) Patent Application Publication
(10) Pub. No.: US 2026/0052660 A1
(43) Pub. Date: Feb. 19, 2026

(54) SINGLE-PHASE UPS LIQUID COOLING

(71) Applicant: VERTIV CORPORATION, Westerville, OH (US)

(72) Inventor: Mohammad Sadegh Ainehvand, Monterrey (MX)

(21) Appl. No.: 19/283,986

(22) Filed: Jul. 29, 2025

Related U.S. Application Data
(60) Provisional application No. 63/683,001, filed on Aug. 14, 2024.

(51) Int. Cl. H05K 7/20

(52) U.S. Cl. CPC H05K 7/209; H05K 7/20454; H05K 7/20927

(57) ABSTRACT

A method may include removing a housing of the power component, wherein removing the housing reveals an air-cooled heat sink. A method may include thermally coupling the liquid-cooled heat sink to one or more elements of the power component. A method may include coupling the liquid-cooled heat sink to a liquid cooler. A method may include replacing the housing.

### CROSS-REFERENCE TO RELATED APPLICATIONS

The present application claims the benefit under 35 U.S.C. § 119 (e) of U.S. Provisional Patent Application Ser. No. 63/683,001 filed Aug. 14, 2024, which is incorporated herein by reference in its entirety.

### TECHNICAL FIELD

The present disclosure relates to thermal control systems for electronic equipment, and more particularly to heat sinks for power components.

### BACKGROUND

Single-phase uninterruptible power supply (UPS) systems typically utilize air cooling, which presents several limitations when adapting these systems for high power density applications. Air cooling is not suitable for high-power density setups due to lower thermal capacity and thermal density aspects. Consequently, conventional UPS systems employing air cooling mechanisms tend to be larger in size and generate considerable noise. Moreover, the elevated temperatures of the semiconductors resulting from air cooling diminish the power quality and efficiency of the UPS. Additionally, the design necessitates a significant amount of empty space for air circulation, further contributing to the large space required to house the UPS.

It is currently not feasible to retrofit current air-cooled UPS systems for use in liquid cooling racks, particularly those intended for artificial intelligence (AI)-utilizing servers, referred to as “AI servers”. AI servers predominantly rely on liquid cooling technology, and the increasing power demands of AI servers exacerbate the limitations of air-cooled UPS systems. Attempting to power such systems with air-cooled UPS units would result in excessively bulky installations unable to meet power demands efficiently. Accordingly, it may be advantageous to have UPS systems for high power density applications that can overcome the difficulties of providing cooling than current systems as described above.

### SUMMARY

Accordingly, the present disclosure is directed toward a power component that includes a liquid-cooled heat sink, and a method for converting a power component that includes an air-cooled heat sink into a power component that includes a liquid-cooled heat sink.

In some aspects, the techniques described herein relate to a method of implementing a liquid-cooled heat sink in an air-cooled power component including: removing a housing of the air-cooled power component, wherein removing the housing reveals an air-cooled heat sink; thermally coupling the liquid-cooled heat sink to one or more elements of the air-cooled power component; coupling to the liquid-cooled heat sink to a liquid cooler; and replacing the housing.

In some aspects, the techniques described herein relate to a method of implementing a liquid-cooled heat sink in an air-cooled power component including: removing a housing of the air-cooled power component, wherein removing the housing reveals an air-cooled heat sink; removing the air-cooled heat sink; thermally coupling the liquid-cooled heat sink to one or more elements of the air-cooled power component; coupling to the liquid-cooled heat sink to a liquid cooler; and replacing the housing.

In some aspects, the techniques described herein relate to a power component configured to output an output power to a load including: a rectifier configured to receive AC power and output at least one of an intermediate power or the output power: a battery electrically coupled to the rectifier; a control system electrically coupled to the rectifier including one or more switching devices; an air-cooled heat sink thermally coupled to one or more elements of the power component; and a liquid-cooled heat sink thermally coupled to at least one of the one or more elements of the power component or the air cooled heat sink.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE FIGURES

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims.

FIG. 1A illustrates a block diagram of a power component, in accordance with one or more embodiments of the disclosure.

FIG. 1B illustrates a block diagram of a power component, in accordance with one or more embodiments of the disclosure.

FIG. 2A illustrates a perspective view of a power component with a top section of the housing removed, in accordance with one or more embodiments of the disclosure.

FIG. 2B illustrates a perspective view of a power component (e.g., a single-phase UPS) with a top section of the housing removed, in accordance with one or more embodiments of the disclosure.

FIG. 3A illustrates a process flow diagram depicting a method for implementing a liquid-cooled heat sink in an air-cooled power component, in accordance with one or more embodiments of the disclosure.

FIG. 3B illustrates a process flow diagram depicting a method for implementing a liquid-cooled heat sink in an air-cooled power component, in accordance with one or more embodiments of the disclosure.

FIG. 4A illustrates a perspective view of a liquid-cooled heat sink, in accordance with one or more embodiments of the disclosure.

FIG. 4B illustrates a perspective view of a power component with a top section of the housing removed, in accordance with one or more embodiments of the disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present), and B is false (or not present), A is false (or not present) and B is true (or present), and both A and B are true (or present).

In addition, the use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “embodiments” means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Disclosed is a power component that includes a liquid-cooled heat sink, and a method for converting a power component that includes an air-cooled heat sink into a power component that includes a liquid-cooled heat sink. The power component may be any device that converts incoming power, such as mains power or utility power, into an output power used for processing. The liquid-cooled heat sink may be added to a power component containing an air-cooled heat sink (e.g., creating a hybrid power component containing both air-cooled and liquid-cooled heat sinks) or may replace the air-cooled heat sink.

Embodiments of the present disclosure are particularly advantageous for thermal control of power components that power high-use processing units, such as AI/ML servers, high-performance computing (HPC) servers, or other processor-intensive servers built for high performance. For example, methods of the current disclosure may be used to convert existing power components to liquid cooling without requiring major changes to power component design or necessitating high labor and/or cost inputs. The addition of liquid cooling to power components may also reduce audible noise generated by the power components.

Embodiments of the present disclosure may also enable changes in power component design, allowing the production of power components with smaller physical dimensions due to space-saving aspects of liquid cooling. These changes in power component design may also include changes that cause the power component to be resistant to environmental factors such as dust, water ingress, and humidity, which may increase reliability and durability in challenging operating conditions, including unique environments such as the high-humidity environments of ports or cargo ships. The addition of liquid cooling to power components may also result in more efficient and power-saving cooling.

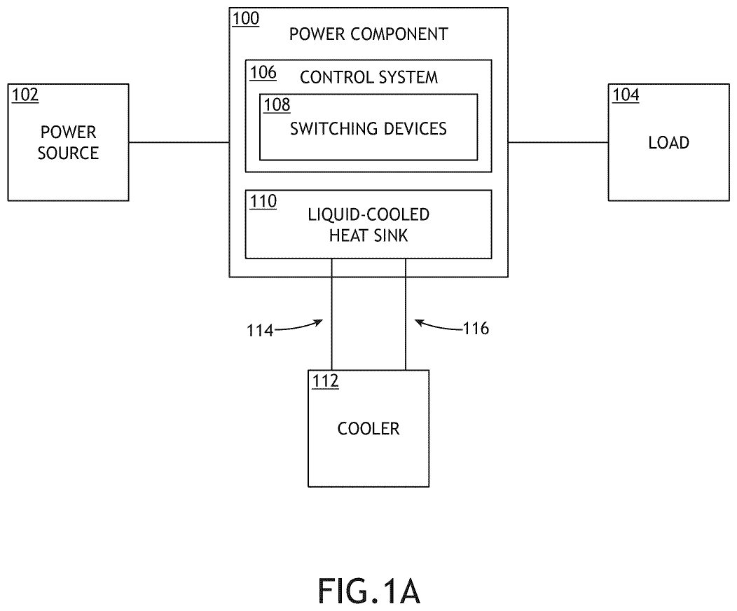

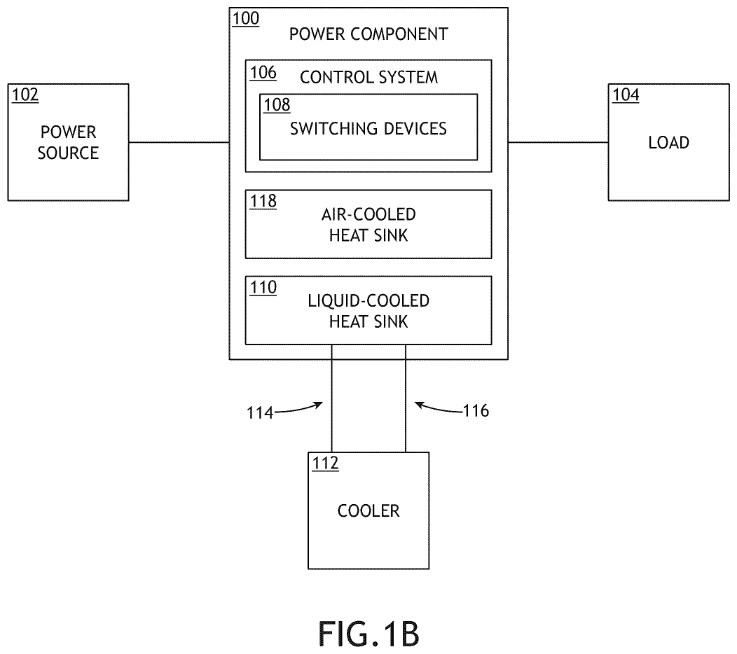

FIG. 1A illustrates a block diagram of a power component 100, in accordance with one or more embodiments of the disclosure. The power component 100 may receive power from a power source 102 (e.g., mains power or utility power) and deliver power to a 104. The power component 100 may provide power conversion and/or distribution and may be configured as a power supply, a power distribution unit (PDU), a static transfer switch (STS), a power shelf, a rack power distribution unit, or other power conversion and/or power distribution device. For example, the power component 100 may include or be configured as an uninterruptible power supply (UPS). For instance, the power component 100 may be configured as a single-phase UPS (e.g., single-phase AC power). In another instance, the power component 100 may be configured as a three-phase UPS.

In embodiments, the power component 100 includes a control system 106 configured to control power conversion and/or power distribution aspects of the power component 100. For example, the control system 106 may include, but not be limited to, rectifiers, inverters, and converters. The control system 106 may further include one or more power switching devices 108 including, but not limited to, an insulated gate bipolar transistor (IGBT), a metal-oxide-semiconductor field-effect transistor (MOSFET), a silicon-controlled rectifier (SCR), a power diode, a power IGBT module, a power thyristor, gallium nitride (GaN) semiconductors/transistors, silicon carbide semiconductors/transistors, and an integrated gate-commuted thyristor (IGCT).

In embodiments, the power component is configured as a UPS that includes a rectifier configured to receive AC power and output at least one of an intermediate power (e.g., for charging a battery) or an output power (for powering the load 104 and/or charging the battery). The UPS may further include a battery electrically coupled to the rectifier. The UPS may further include an inverter that receives the output from the rectifier and supplies DC power to the load.

In embodiments, the power component 100 includes a liquid-cooled heat sink 110 configured to remove heat from elements within the power component 100, such as from the one or more switching devices 108 of the control system 106. For example, the liquid-cooled heat sink 110 may be thermally coupled and/or adhered to the one or more switching devices 108. The liquid-cooled heat sink 110 may be of any type, size, or shape. For example, the liquid-cooled heat sink 110 may include, but not be limited to, cold plates, heat pipe heat sinks, hybrid heat sinks, microchannel heat sinks, jet impingement heat sinks, phase change material (PCM) heat sinks, thermosyphon heat sinks, and direct liquid cooling heat sink elements.

In embodiments, the power component may include or be coupled to a liquid cooler 112 configured to remove heat from the liquid-cooled heat sink 110 through the circulation of a coolant. The liquid cooler 112 may be coupled to the liquid-cooled heat sink 110 via tubes and/or piping that includes a liquid input 114 and a liquid output 116, supplying coolant to and from the liquid-cooled heat sink 110. The liquid cooler 112 may include any type of liquid cooling and circulating device including, but not limited to, a pump, such as a brushless pump. The liquid cooler 112 may also include, but not be limited to, cold plates, radiators, fans, and heat exchangers. The coolant used may include, but not be limited to, water, glycol-water mixtures, fluorocarbon liquids, mineral oil, dielectric fluids, nanofluids, two-phase fluids, and hybrid coolants.

FIG. 1B illustrates a block diagram of a power component 100, in accordance with one or more embodiments of the disclosure. In embodiments, the power component 100 includes an air-cooled heat sink 118 thermally coupled to one or more elements of the power component 100 in addition to the one or more liquid-cooled heat sink 110. For example, the air-cooled heat sink 118 may be thermally coupled to one or more switching devices 108 of the control system 106.

In embodiments, the air-cooled heat sink 118 is a passive heat sink. For example, the air-cooled heat sink 118 may include, but not be limited to, a stamping/sheet metal heat sink, a bonded fin heat sink, an extruded heat sink, a folded fin heat sink, a pin fin heat sink, a swaged heat sink, or a skived/finned heat sink. In embodiments, the air-cooled heat sink 118 includes an active heat sink. For example, the air-cooled heat sink 118 may include heat pipes or thermoelectric liquid coolers (TECs).

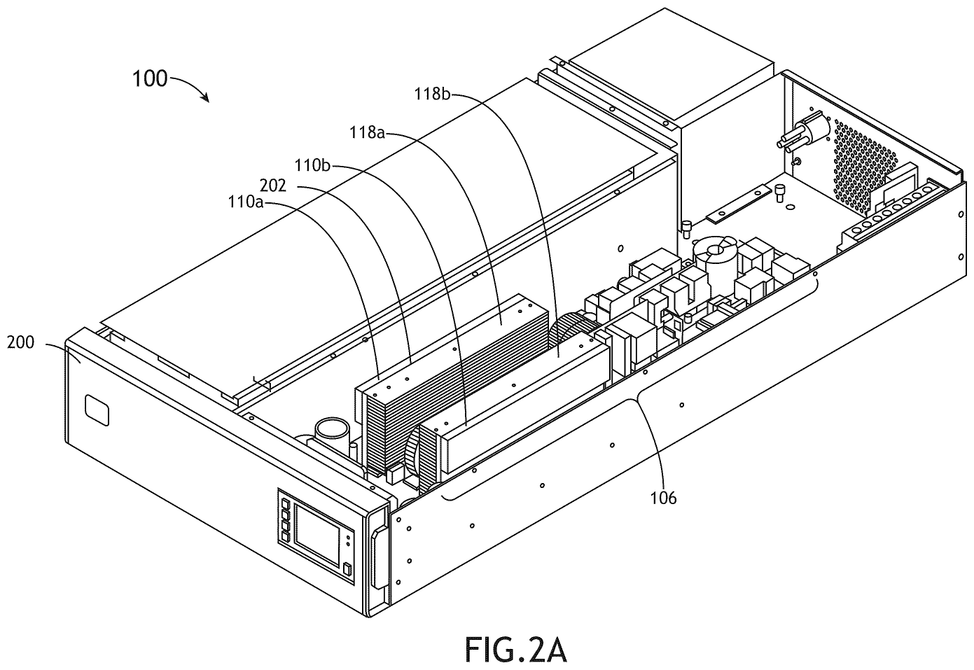

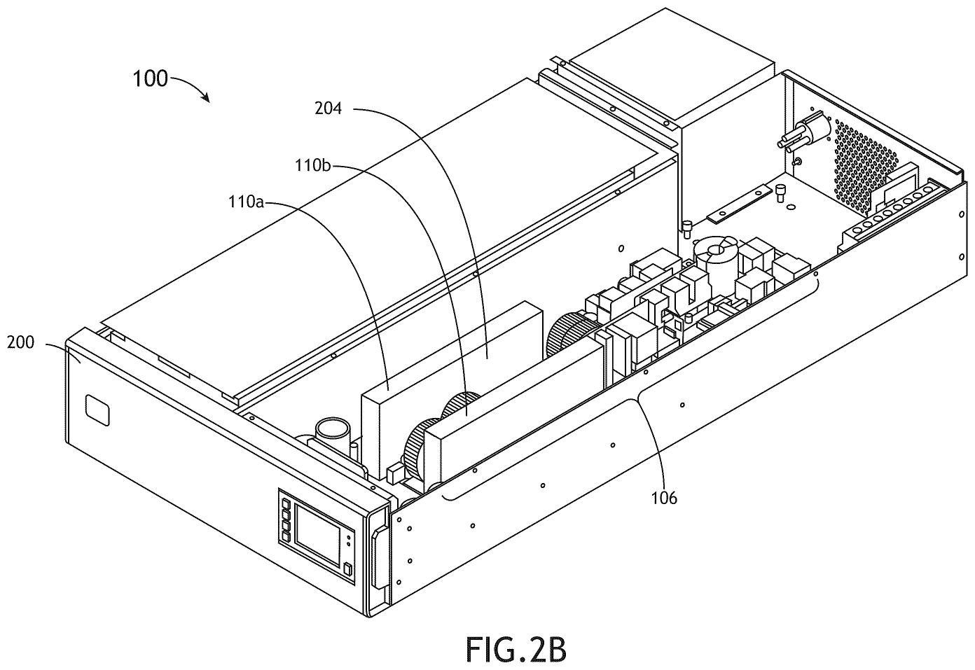

FIG. 2A illustrates a perspective view of a power component 100 (e.g., a single-phase UPS) with a top section of the housing 200 removed, in accordance with one or more embodiments of the disclosure. The power component 100 includes two air-cooled heat sinks 118a-b thermally coupled to, and partially enclosing, the control system 106.

In embodiments, the liquid-cooled heat sink 110 is thermally coupled and/or adhered to the air-cooled heat sink 118. For example, a power component 100 that has been originally designed and/or constructed with an air-cooled heat sink 118, but not a liquid-cooled heat sink 110, may have one or more liquid-cooled heat sinks 110a-b adhered or bonded to the one or more air-cooled sinks 118a-b. For instance, one or more air-cooled sink surfaces 202 (e.g., largely hidden from view in FIG. 2A) may be adhered or bonded to one or more water-cooled sink surfaces 202 (e.g., as shown in FIG. 2B). The adhering and/or bonding of the one or more air-cooled heat sinks 118a-b to the one or more liquid-cooled heat sinks 110a-b may be accomplished via clamping (e.g., mounting brackets, clamps, or clips), fasteners, screws (e.g., spring-loaded screws) backplates, adhesive pads (e.g., adhesive thermal pads), adhesive tape (e.g., adhesive thermal tape), glue, or other thermal interface material such as thermal paste, thermal pads, or thermal grease.

FIG. 2B illustrates a perspective view of a power component 100 (e.g., a single-phase UPS) with a top housing removed, in accordance with one or more embodiments of the disclosure. The power component 100 includes two liquid-cooled heat sinks 110a-b thermally coupled to, and partially enclosing, the control system 106.

In embodiments, the water-cooled sink surface 204 of the liquid-cooled heat sinks 110 used to adhere and/or bond to the air-cooled heat sink 118 has a surface area (e.g., surface area that is bound to air-cooled heat sink surface 202 of the air-cooled heat sink 118) of less than 20 cm², of less than 10 cm², or of less than 5 cm². For example, the surface area of the water-cooled sink surface 204 adhered to the air-cooled heat sink 118 may have a surface area of approximately 4.8 cm². For instance, the surface area of the water-cooled sink surface 204 adhered to the air-cooled heat sink 118 may have dimensions of 40 mm×120 mm. The dimensions of the water-cooled sink surface 204 need to be small enough to fit within the confines of the housing 200, yet efficient enough to cool the electronic elements.

In embodiments, the power component 100 is a device that was originally constructed with one or more air-cooled heat sinks 118a-b that have been replaced with one or more liquid-cooled heat sinks 118a-b. For example, the replacement of one or more liquid-cooled heat sinks 118a-b may be thermally coupled to one or more elements of the power component 100 (e.g., the control system 106) that was originally coupled to the one or more air-cooled heat sinks 118. For instance, a replacement liquid-cooled heat sink 110 may be positioned so that at least a portion of the liquid-cooled heat sink 110 overlaps with the original position of at least a portion of the replaced air-cooled heat sink 118.

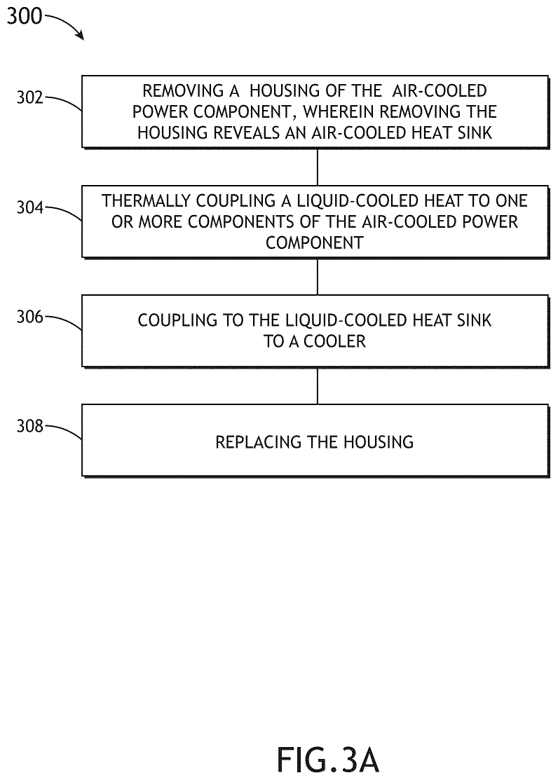

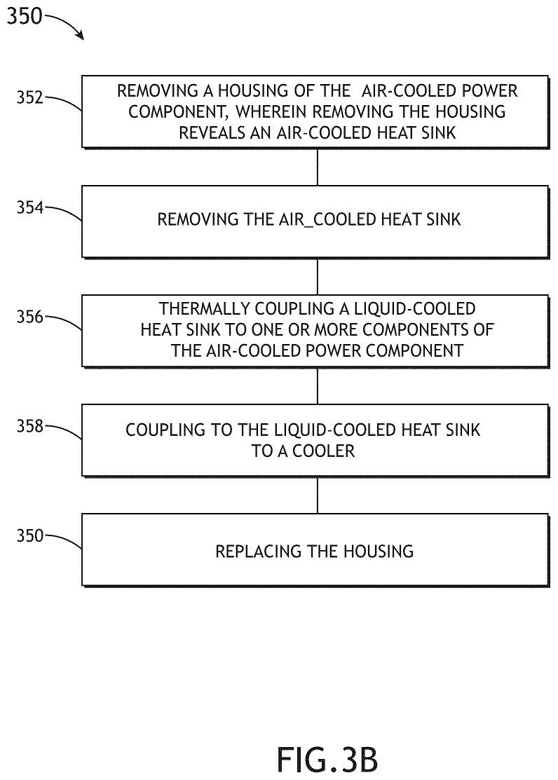

FIG. 3A illustrates a process flow diagram depicting a method 300 for implementing a liquid-cooled heat sink in an air-cooled power component, in accordance with one or more embodiments of the disclosure. The method 300 may be used for producing the power components 100 as illustrated in FIGS. 1A-B. In embodiments, the method 300 includes a step 302 of removing a housing 200 (e.g., a top section of the housing 200) of the power component 100, wherein removing the housing 200 reveals an air-cooled heat sink 118. For the production of new power components 100, the housing may have yet to be positioned.

In embodiments, the method 300 includes a step 304 of thermally coupling the liquid-cooled heat sink 110 to one or more elements of the air-cooled power component 100. For example, the liquid-cooled heat sink 110 may be thermally coupled and/or bonded/adhered to the control system 106 and/or one or more switching devices 108 of the control system 106. In another example, one or more liquid-cooled heat sinks 110 may be coupled to one or more air-cooled heat sinks 118 as described herein. By adding a liquid-cooled heat sink 110 to a power component 100 containing an air-cooled heat sink 118, a hybrid-cooled power component 100 is created.

In embodiments, the method 300 includes a step 306 of coupling to the liquid-cooled heat sink 110 to a liquid cooler 112. For example, the liquid-cooled heat sink 110 may include a set of coolant ports that are couplable to respective liquid cooler ports via tubing. In embodiments, the method includes a step 308 of replacing the housing 200.

In embodiments, the method 300 includes a step of removing the air-cooled heat sink 118 from the air-cooled power component 100. For example, once the housing 101 is removed, the air-cooled heat sink 118 may be removed and replaced by the liquid-cooled heat sink 110, as described herein.

FIG. 3B illustrates a process flow diagram depicting a method 350 for implementing a liquid-cooled heat sink in an air-cooled power component, in accordance with one or more embodiments of the disclosure. The method 300 may be used for producing the power components 100 as illustrated in FIG. 1A.

In embodiments, the method includes a step 352 of removing a housing 200 (e.g., a top section of the housing 200) of the air-cooled power component 100, wherein removing the housing 200 reveals an air-cooled heat sink 118. In embodiments, the method 350 includes a step 354 of removing the air-cooled heat sink 118. In embodiments, the method 350 includes a step 356 of thermally coupling a liquid-cooled heat sink 110 to one or more elements of the air-cooled power component 100. In embodiments, the method 350 includes a step 358 of coupling to the liquid-cooled heat sink to a liquid cooler 112. In embodiments, the method 350 includes a step 360 of replacing the housing 200.

### EXAMPLES

The following Examples are illustrative and should not be interpreted to limit the scope of the claimed subject matter.

### Example 1: Coupling Two Cooling Aluminum Heat Sinks to an Original Air-Cooled Heat Sink 118 of a UPS

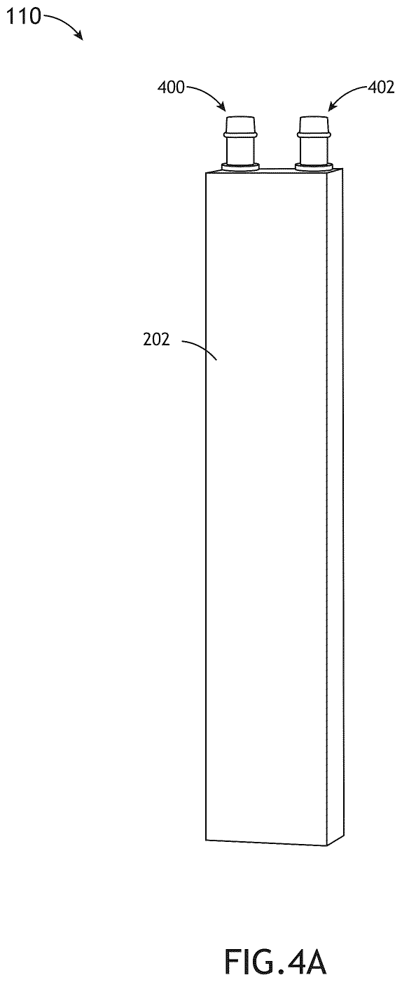

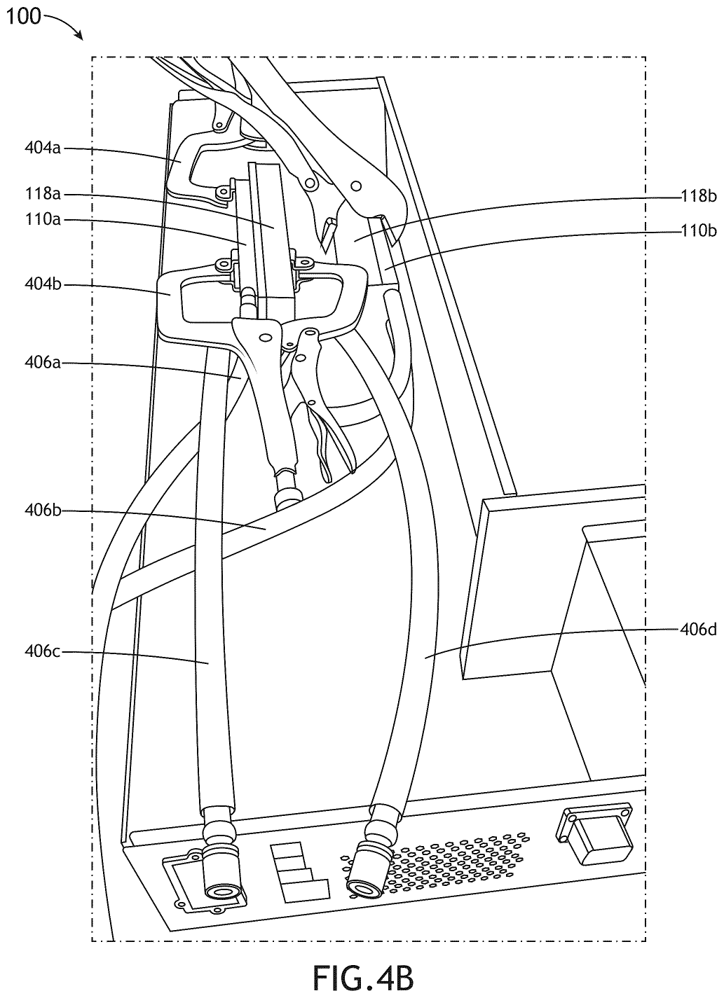

Two liquid-cooling aluminum heat sinks are used for connecting to the original air-cooling heat sinks. Dimensions of the liquid-cooled heat sinks 110 are (40 mm×120 mm×12 mm), as shown in FIG. 4A. The shape of the liquid-cooled heat sink 110 can be different based on the air-cooling heat sink 118.

FIG. 4B illustrates a perspective view of a power component 100 (e.g., UPS) with a housing removed, in accordance with one or more embodiments of the disclosure. The original air-cooled heat-sinks 118a-b of the UPS are shown clamped to respective liquid-cooled heat sinks 110a-b via clamps 404a-c. Liquid is circulated within the liquid-cooled heat sink 110 via an inlet port 400 and an outlet port 402. Liquid is circulated to and from the liquid-cooled heat sinks via tubing 406a-d. Tubing 406a-d is coupled to the inlet ports 400 and receives cold water via a pump. Tubing 406c-d is coupled to the outlet ports 402. Coolant (e.g., water) was cooled to approximately 8° C. before circulating through the liquid-cooled heat.

### Results

While the UPS was in active mode (e.g., supplying 97% load), the liquid-cooled heat sink removed heat from the UPS, which appeared to improve UPS function by raising UPS efficiency from 91.14% to 94.3%, as shown in Table 1.

TABLE 1

| UPS with liquid-cooled and | | | | | | | |
|---|---|---|---|---|---|---|---|
| air-cooled heat sink | | | | UPS with air-cooled heat sink | | | |
| | | Heat | UPS | | | Heat | UPS |
| Load | Liquid | sink | efficiency | Load | ambient | sink | efficiency |
| 97% | Water | 13 C. | 94.3% | 97% | 21 C. | 50 C. | 91.14% |
| | 8 C. | | | | | | |

### DISCUSSION

Leveraging liquid cooling technology can potentially condense UPS units, enabling a higher power density. For instance, transitioning from a 10KVA 3U UPS to a 10KVA 1U UPS. Lowering semiconductor temperatures through liquid cooling can significantly reduce power losses, enhancing efficiency by up to 40% across elements like inverters, rectifiers, and power factor correction modules. Lower temperatures on semiconductors extend the lifespan of electronic elements, with capacitors experiencing up to a twofold increase in longevity compared to air cooling. Reduced semiconductor temperatures lead to higher switching frequencies, resulting in improved power output quality and increased resistance against non-linear loads. Liquid cooling systems replace noisy air-cooling fans, resulting in a significant reduction in operational noise. Liquid cooling technology reduces overall cooling system costs by replacing traditional air-cooling methods with more efficient liquid-based solutions. Enhancing system efficiency and reducing energy consumption for cooling operations contribute to a greener, more sustainable approach, lowering carbon emissions. Implementing liquid cooling can boost the same UPS power delivery by up to 20%, meeting the growing demands of modern data centers. Liquid-cooled UPS solutions align with the evolving needs of AI-based and HPC-based server rooms, catering to the demands of cutting-edge technology applications. Since the shape of the liquid cooling heatsink is customizable, any UPS may be to liquid cooling or hybrid cooling via the techniques described herein.

The herein-described subject matter sometimes illustrates different components (e.g., elements) contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Those skilled in the art will recognize that it is common within the art to describe devices and/or processes in the fashion set forth herein, and thereafter use engineering practices to integrate such described devices and/or processes into power and/or data processing systems. That is, at least a portion of the devices and/or processes described herein can be integrated into a data processing system via a reasonable amount of experimentation. Those having skill in the art will recognize that a typical power and/or data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical power and/or data processing system may be implemented utilizing any suitable commercially available components, such as those typically found in power and/or data computing/communication and/or network computing/communication systems.

It is further contemplated that each of the embodiments of the method described above may include any other step(s) of any other method(s) described herein. In addition, each of the embodiments of the method described above may be performed by any of the systems described herein.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed is:

1. A method of implementing a liquid-cooled heat sink in an air-cooled power component comprising:
removing a housing of the air-cooled power component, wherein removing the housing reveals an air-cooled heat sink;
thermally coupling the liquid-cooled heat sink to one or more elements of the air-cooled power component;
coupling to the liquid-cooled heat sink to a liquid cooler; and
replacing the housing.

2. The method of claim 1, wherein thermally coupling the liquid-cooled heat sink to one or more elements of the air-cooled power component comprises thermally coupling the liquid-cooled heat sink to the air-cooled heat sink.

3. The method of claim 1, wherein the liquid-cooled heat sink to the air-cooled heat sink are thermally coupled via thermal grease.

4. The method of claim 1, wherein thermally coupling the liquid-cooled heat sink to one or more elements of the air-cooled power component comprises adhering a water-cooled sink surface of the liquid-cooled heat sink to an air-cooled sink surface of the air-cooled heat sink.

5. The method of claim 4, wherein the water-cooled sink surface of the liquid-cooled heat sink is adhered to the air-cooled sink surface of the air-cooled heat sink via a clamp.

6. The method of claim 5, wherein the water-cooled sink surface of the liquid-cooled heat sink is adhered to the air-cooled sink surface of the air-cooled heat sink via an adhesive.

7. The method of claim 4, wherein the water-cooled sink surface adhered to the air-cooled sink surface comprises an area less than 20 cm².

8. The method of claim 4, wherein the water-cooled sink surface adhered to the air-cooled sink surface comprises an area less than 5 cm².

9. The method of claim 1, wherein the one or more elements comprises a switching device.

10. The method of claim 9, wherein the switching device comprises at least one of a metal-oxide-semiconductor field-effect transistor (MOSFET) or an insulated gate bipolar transistor (IGBT).

11. The method of claim 1, wherein the air-cooled power component comprises an uninterruptible power supply (UPS).

12. A method of implementing a liquid-cooled heat sink in an air-cooled power component comprising:
removing a housing of the air-cooled power component, wherein removing the housing reveals an air-cooled heat sink;
removing the air-cooled heat sink;
thermally coupling a liquid-cooled heat sink to one or more elements of the air-cooled power component;
coupling to the liquid-cooled heat sink to a liquid cooler; and
replacing the housing.

13. The method of claim 12, wherein the one or more elements comprises a switching device.

14. The method of claim 13, wherein the switching device comprises at least one of a metal-oxide-semiconductor field-effect transistor (MOSFET) or an insulated gate bipolar transistor (IGBT).

15. A power component configured to output an output power to a load comprising:
a rectifier configured to receive AC power and output at least one of an intermediate power or the output power:
a battery electrically coupled to the rectifier;
a control system electrically coupled to the rectifier comprising one or more switching devices;
an air-cooled heat sink thermally coupled to one or more elements of the power component; and
a liquid-cooled heat sink thermally coupled to at least one of the one or more elements of the power component.

16. The power component of claim 15, wherein the liquid-cooled heat sink is adhered to the air-cooled heat sink.

17. The power component of claim 15, wherein the power component is configured to receive single-phase AC power.

18. The power component of claim 15, wherein the power component comprises an uninterruptible power supply (UPS).

19. The power component of claim 15, wherein the liquid-cooled heat sink comprises a water-cooled sink surface thermally coupled to an air-cooled sink surface of the air-cooled heat sink, wherein the liquid-cooled heat sink comprises an area less than 20 cm².

20. The power component of claim 15, wherein the liquid-cooled heat sink comprises a water-cooled sink surface thermally coupled to an air-cooled sink surface of the air-cooled heat sink, wherein the liquid-cooled heat sink comprises an area less than 5 cm².
